(19) United States
(12) Patent Application Publication
(10) Pub. No.: US 2026/0031111 A1
(43) Pub. Date: Jan. 29, 2026

(54) VOLTAGE GENERATOR AND MEMORY DEVICE INCLUDING THE SAME

(71) Applicant: SAMSUNG ELECTRONICS CO., LTD., Suwon-si (KR)

(72) Inventors: Seongjin Kim, Suwon-si (KR); Hanseul Kim, Suwon-si (KR); Jisu Kim, Suwon-si (KR); Se-Heon Baek, Suwon-si (KR)

(21) Appl. No.: 19/197,299

(22) Filed: May 2, 2025

(30) Foreign Application Priority Data
Jul. 29, 2024 (KR) 10-2024-0100484

(51) Int. Cl. G11C 5/14; H02M 3/07

(52) U.S. Cl. CPC G11C 5/147; H02M 3/07

(57) ABSTRACT

The present disclosure relates to voltage generators. An example voltage generator includes a charge pump configured to perform an amplifying operation on an input voltage, a counting block configured to count a number of state transitions of a first clock signal for a reference time and control the charge pump based on the number of state transitions, and a timer configured to initialize the number of state transitions based on the reference time being elapsed.

### CROSS-REFERENCE TO RELATED APPLICATION

This application claims the benefit of Korean Patent Application No. 10-2024-0100484, filed on Jul. 29, 2024, in the Korean Intellectual Property Office, the disclosure of which is incorporated herein by reference.

### BACKGROUND

A voltage generator may generate voltages for operating various electronic devices such as a memory device. As data throughput and transmission speed of memory devices have increased recently, current consumption is rising in the voltage generator. Accordingly, a manner of efficiently controlling current consumption within limited environments is desired.

### SUMMARY

The present disclosure relates to a voltage generator that efficiently controls current consumption and a memory device including the same.

Example implementations are not limited to the technical features described above, and other technical features may be inferred from the example implementations below.

In some implementations, a voltage generator includes a charge pump configured to perform an amplifying operation on an input voltage, a counting block configured to count a number of state transitions of a first clock signal for a reference time and control the charge pump based on the number of state transitions, and a timer configured to initialize the number of state transitions when the reference time elapses.

In some implementations, a voltage generator includes a timer configured to output a reset signal when a reference time elapses, a plurality of oscillators configured to output reference clock signals having reference frequencies independent of each other, and a plurality of charge pump blocks configured to generate a first clock signal based on a reference clock signal received from a connected oscillator among the plurality of oscillators, count a number of state transitions of the first clock signal until the reset signal is received, and perform an amplifying operation on an input voltage based on the number of state transitions. A number of the plurality of charge pump blocks may be greater than or equal to a number of the plurality of oscillators.

In some implementations, a memory device includes a cell array including a plurality of memory cells and a voltage generator configured to generate an operating voltage applied to at least one memory cell among the plurality of memory cells, and the voltage generator may include a charge pump configured to perform an amplifying operation on an input voltage based on a clock signal and generate the operating voltage, a counting block configured to count a number of state transitions of the clock signal for a reference time and control the charge pump based on the number of state transitions, and a timer configured to initialize the number of state transitions when the reference time elapses.

Additional aspects of example implementations will be set forth in part in the description which follows and, in part, will be apparent from the description, or may be learned by practice of the disclosure.

According to example implementations of the present disclosure, it is possible to provide a voltage generator that efficiently controls current consumption and a memory device including the same. According to example implementations of the present disclosure, it is possible to control current consumption more minutely. According to example implementations of the present disclosure, it is possible for a voltage generator to control a charge pump block independently.

Effects of example implementations are not limited to the aforementioned effects, and other unstated effects may be clearly understood by those skilled in the art from the appended claims.

### BRIEF DESCRIPTION OF THE DRAWINGS

These and/or other aspects, features, and advantages of the present disclosure will become apparent and more readily appreciated from the following description of example implementations, taken in conjunction with the accompanying drawings.

FIG. 1 is a diagram illustrating an example of a voltage generator.

FIG. 2 is a diagram illustrating an example of a counting block that controls a charge pump.

FIG. 3 is a diagram illustrating waveforms of an example of a clock signal.

FIG. 4 is an example diagram illustrating the number of state transitions.

FIG. 5 is a diagram illustrating an example of a voltage generator including a plurality of charge pump blocks.

FIG. 6 is a diagram illustrating an example of a voltage generator including a plurality of oscillators.

FIG. 7 is a diagram illustrating an example of a counting block that controls a power transmission part.

FIG. 8 is a diagram illustrating an example of a counting block that controls a regulator.

FIG. 9 is a diagram illustrating waveforms of an example of a clock signal.

FIG. 10 is a diagram illustrating an example of a counting block that controls an oscillator.

FIG. 11 is a diagram illustrating an example of a counting block that controls a loading part.

FIG. 12 is a diagram illustrating an example of current consumption.

FIG. 13 is a diagram illustrating an example of a memory device.

### DETAILED DESCRIPTION

Terms used in example implementations are selected from currently widely used general terms when possible while considering the functions in the present disclosure. However, the terms may vary depending on the intention of a person skilled in the art, precedents, the emergence of new technology, and the like. Further, in certain cases, there are also terms arbitrarily selected by the applicant, and in these cases, the meaning will be described in detail in the corresponding descriptions. Therefore, the terms used in the present disclosure are not to be construed simply as its designation but based on the meaning of the term and the overall context of the present disclosure.

Throughout the specification, when a part is described as “comprising or including” a component, it does not exclude another component but may further include another component unless otherwise stated. Furthermore, terms such as “ . . . unit,” “ . . . part,” and “ . . . module” described in the specification mean a unit that processes at least one function or operation, which may be implemented as hardware, software, or a combination thereof.

Hereinafter, example implementations of the present disclosure will be described in detail with reference to the accompanying drawings so that those of ordinary skill in the art to which the present disclosure pertains may easily implement them. However, the present disclosure may be implemented in multiple different forms and is not limited to the example implementations described herein.

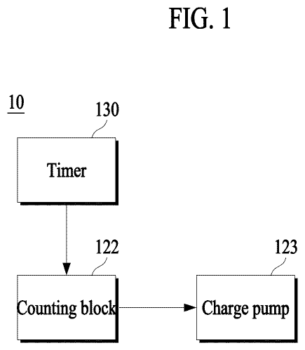

FIG. 1 is a diagram illustrating an example of a voltage generator.

Referring to FIG. 1, a voltage generator 10 may generate an operating voltage for operating an electronic device. In some example implementations, the electronic device may be, but is not limited to, a memory device, and the electronic device may be various types of devices such as a smartphone, a tablet, a computer, mobility equipment (for example, automobile, drone, vessel, aircraft), industrial equipment (for example, robot, semiconductor process equipment), wearable devices (for example, smart watch, smart ring, smart glasses), a camera, communication devices (for example, router, repeater), household appliances (for example, washing machine, refrigerator), medical appliances (for example, magnetic resonance apparatus, ultrasound apparatus, X-ray inspection apparatus), and display devices (for example, television, monitor).

In some example implementations, the voltage generator 10 may be disposed inside the electronic device. In other words, the voltage generator 10 may be included in the electronic device. In this case, the voltage generator 10 may be connected to other components included in the electronic device through a bus. In some example implementations, the voltage generator 10 may be disposed outside the electronic device. In this case, the voltage generator 10 may be connected to the electronic device through a power connector.

The voltage generator 10 may generate an operating voltage using an input voltage and then output. The operating voltage may be a voltage used for the electronic device to perform a specific operation. For example, the operating voltage may include at least one of a program voltage for storing data in a memory cell, a read voltage for reading data stored in the memory cell, an erase voltage for erasing data stored in the memory cell, a pass voltage applied to an unselected word line, a verification voltage for verifying a state of the memory cell, and a power voltage for operating a peripheral circuit.

The voltage generator 10 may include a charge pump 123, a counting block 122, and a timer 130.

The charge pump 123 may perform an amplifying operation on an input voltage. For example, the input voltage may be supplied to the charge pump 123 from an external power source or an internal power source of the electronic device. The amplifying operation may be an operation of increasing a level of the input voltage. In some example implementations, the charge pump 123 may perform the amplifying operation based on a clock signal. The charge pump 123 may provide an output voltage having a higher level than the input voltage by performing the amplifying operation.

In some example implementations, the charge pump 123 may include a capacitor that is charged and discharged depending on a state of a clock signal. For example, when the clock signal is in a first state (for example, low state), the input voltage may be connected to one end of the capacitor and a ground voltage may be connected to another end of the capacitor and thus the capacitor may be charged. In this case, a voltage of the capacitor may become equal to the input voltage. Further, when the clock signal is in a second state (for example, high state), the input voltage may be connected to another end of the capacitor and thus a voltage of the capacitor may be twice the input voltage. When the clock signal periodically repeats state transition, repeatedly performing the operations described above may increase a voltage level in stages. In some example implementations, the charge pump 123 may further include a switching element and/or diode to control a current flow. However, this is merely one example implementation, and the charge pump 123 may be implemented as various types of circuits such as the Dickson charge pump, complementary metal oxide semiconductor (CMOS) charge pump, and the like.

The counting block 122 may count the number of state transitions of the clock signal for a reference time. For example, the counting block 122 may include an input pin that receives the clock signal. When the clock signal is in an active mode, the state of the clock signal may be periodically transitioned depending on frequencies. When the clock signal is in an inactive mode, the state of the clock signal may be maintained.

In some example implementations, the counting block 122 may count the number of state transitions of the clock signal, incrementing by one each time a state transition of the received clock signal occurs. In some example implementations, the state transition may indicate that the first state of the clock signal changes to the second state. For example, when the first state is a low state and the second state is a high state, the counting block 122 may increase (or decrease) the number of state transitions by once whenever a rising edge is generated in the clock signal. For another example, when the first state is a high state and the second state is a low state, the counting block 122 may increase (or decrease) the number of state transitions by once whenever a falling edge is generated in the clock signal. For example, the counting block 122 may include a flip-flop toggled at the rising edge or the falling edge of the clock signal.

The counting block 122 may control the charge pump 123 based on the number of state transitions. The number of state transitions may be a value accumulated for the reference time.

In some example implementations, the counting block 122 may control the charge pump 123 so that the charge pump 123 operates according to a first mode until the number of state transitions reaches a set value. For example, the first mode may be an operating mode of performing an amplifying operation without limitation. In some example implementations, the counting block 122 may control the charge pump 123 so that the charge pump 123 operates according to a second mode after the number of state transitions reaches a set value. For example, the second mode may be an operating mode of stopping the amplifying operation, delaying the time to perform the amplifying operation, or reducing a voltage inputted to the charge pump 123. Here, the first mode may be a general mode and the second mode may be a low-power mode.

The timer 130 may initialize the number of state transitions when the reference time elapses. In some example implementations, the timer 130 may initialize the number of state transitions of the counting block 122 whenever the reference time elapses. The reference time may refer to a set time period (or time interval). According to the present disclosure, as the first mode is changed to the second mode based on the number of state transitions within the reference time, and the number of state transitions is initialized when the reference time elapses, which leads to a change to the first mode back, the current consumption of the voltage generator may be efficiently adjusted by detailed units.

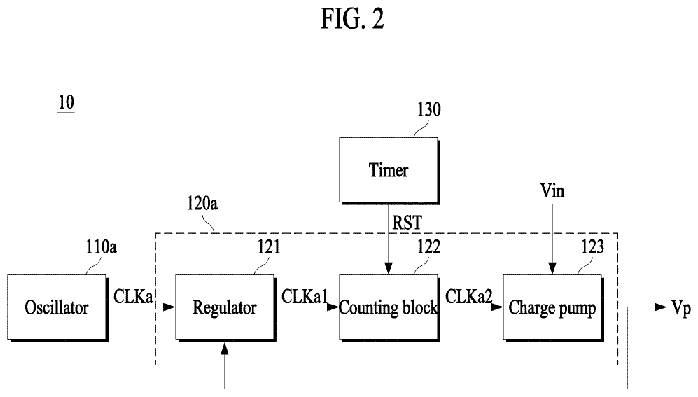

FIG. 2 is a diagram illustrating an example of a counting block that controls a charge pump.

Referring to FIG. 2, the voltage generator 10 may include the charge pump 123, the counting block 122, and the timer 130. In some example implementations, the voltage generator 10 may further include at least one of an oscillator 110a and a regulator 121.

The oscillator 110a may output a reference clock signal CLKa. The oscillator 110a may output a signal having a reference frequency as the reference clock signal CLKa. For example, the signal having the reference frequency may be a signal in which state transition occurs every time period based on the reference frequency. In some example implementations, the oscillator 110a may be implemented as various circuits such as an RC oscillator generating the reference clock signal CLKa, an LC oscillator, and a crystal oscillator.

The regulator 121 may receive the reference clock signal CLKa. In some example implementations, the regulator 121 may output a first clock signal CLKa1 corresponding to the reference clock signal CLKa. For example, the regulator 121 may output the first clock signal CLKa1 having a frequency equal to the reference frequency of the reference clock signal CLKa.

In some example implementations, the regulator 121 may receive an output voltage Vp of the charge pump 123 through feedback. The regulator 121 may compare the output voltage Vp and a reference voltage. The regulator 121 may output the first clock signal CLKa1 corresponding to the reference clock signal CLKa based on a result of comparing the output voltage Vp and the reference voltage. For example, when the output voltage Vp is less than the reference voltage, the regulator 121 may output a signal having a frequency equal to the reference frequency of the reference clock signal CLKa as the first clock signal CLKa1. For example, when the output voltage Vp is equal to or greater than the reference voltage, the regulator 121 may output a signal having a frequency less than the reference frequency of the reference clock signal CLKa as the first clock signal CLKa1. In this case, a time period in which the state transition of the first clock signal CLKa1 occurs may be longer. For another example, when the output voltage Vp is equal to or greater than the reference voltage, the regulator 121 may output a signal in which a state (for example, high state or low state) is maintained as the first clock signal CLKa1. In other words, the regulator 121 may maintain the output voltage Vp at a constant level.

The counting block 122 may count the number of state transitions of the first clock signal CLKa1 received for the reference time. The timer 130 may output a reset signal RST when the reference time elapses. When the reset signal RST is received, the counting block 122 may initialize the number of state transitions of the first clock signal CLKa1. For example, when the reset signal RST is received, the counting block 122 may change the number of state transitions of the first clock signal CLKa1 into an initial value (for example, 0).

The counting block 122 may output a second clock signal CLKa2 corresponding to the first clock signal CLKa1 based on the number of state transitions of the first clock signal CLKa1. The charge pump 123 may perform an amplifying operation based on a state transition of the second clock signal CLKa2.

For example, until the number of state transitions of the first clock signal CLKa1 reaches a set value for the reference time, the counting block 122 may output a signal having a frequency equal to a frequency of the first clock signal CLKa1 as the second clock signal CLKa2. In this case, the charge pump 123 may perform the amplifying operation on an input voltage Vin according to the state transition of the second clock signal CLKa2.

For example, after the number of state transitions of the first clock signal CLKa1 reaches the set value, the counting block 122 may output a signal with state transition stopped as the second clock signal CLKa2. In this case, the charge pump 123 may stop the amplifying operation on the input voltage Vin according to the state transition of the second clock signal CLKa2 being stopped. In other words, the charge pump 123 may stop the amplifying operation on the input voltage Vin according to the state of the second clock signal CLKa2 being maintained (maintained as one of the high state and the low state). Thus, the number of state transitions of the second clock signal CLKa2 may be associated with the number of times performing the amplifying operation.

In some example implementations of the present disclosure, the voltage generator 10 may include at least one charge pump block. For example, the charge pump block may include a first charge pump block 120a. Hereinafter, the first charge pump block 120a will be described, and the description of the first charge pump block 120a may be similarly applicable to other charge pump blocks. The first charge pump block 120a may include the counting block 122 and the charge pump 123. In other words, the counting block 122 and the charge pump 123 connected to each other may be included in the first charge pump block 120a which is one unit group. In some example implementations, the first charge pump block 120a may further include the regulator 121. In other words, the regulator 121, the counting block 122, and the charge pump 123 connected to each other may be included in the first charge pump block 120a which is one unit group.

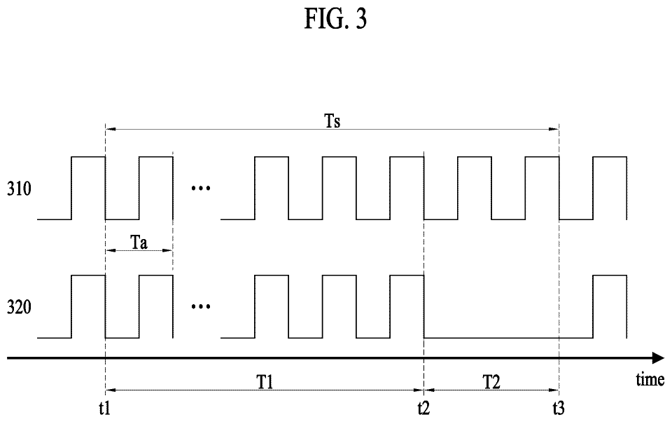

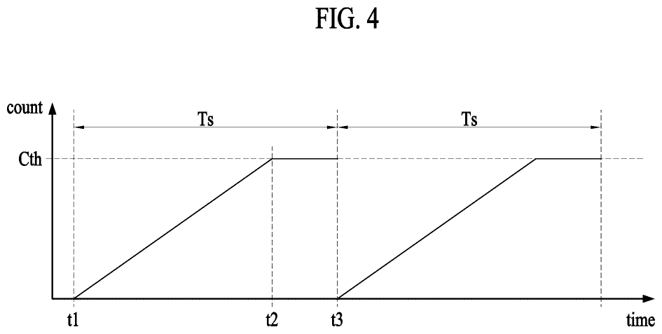

FIG. 3 is a diagram illustrating waveforms of an example of a clock signal. FIG. 4 is an example diagram illustrating the number of state transitions.

Referring to FIG. 3, a first waveform 310 represents a waveform of the first clock signal CLKa1 based on time, and a second waveform 320 represents a waveform of the second clock signal CLKa2 based on time. It is illustrated that time is identical in the waveforms of the first clock signal CLKa1 and the second clock signal CLKa2, but a delay time may be present. Referring to FIG. 4, the number of state transitions of the second waveform 320 of FIG. 3 is shown based on time.

Referring to FIGS. 3 and 4, the first clock signal CLKa1 and the second clock signal CLKa2 may be signals having one state among a first state and a second state depending on voltages. For example, the first state may be a low state and the second state may be a high state. For example, a voltage in the first state may be a ground voltage, and a voltage in the second state may be an input voltage (or other voltages).

A reference time Ts from a first time point t1 to a third time point t3 may be set by the timer 130. For example, a time interval may be set to 0.5 microseconds (μs), 0.6 μs, 1.0 μs, or the like.

The counting block 122 may count the number of state transitions of the first clock signal CLKa1 for the reference time Ts. Here, a state of the first clock signal CLKa1 may be transitioned according to a period Ta corresponding to a frequency. For example, the period Ta may be a time from a rising edge (or falling edge) to a following rising edge (or following falling edge). For example, the counting block 122 may include various types of counter circuits for counting the number of state transitions of the first clock signal CLKa1.

The counting block 122 may compare the number of state transitions of the first clock signal CLKa1 and a set value Cth. The set value Cth may be a preset value in the counting block 122. For example, the counting block 122 may include a comparator circuit that compares the number of state transitions and a set value based on a magnitude relation and outputs a comparison result signal indicating a result of the comparison. At a second time point t2 within the reference time Ts, the number of state transitions of the first clock signal CLKa1 may reach the set value Cth.

The counting block 122 may output the second clock signal CLKa2 having a frequency equal to a frequency of the first clock signal CLKa1 for a first time T1 until the number of state transitions of the first clock signal CLKa1 reaches the set value Cth. The counting block 122 may output the second clock signal CLKa2 with state transition stopped for a second time T2 after the number of state transitions of the first clock signal CLKa1 reaches the set value Cth. For the second time T2, the amplifying operation of the charge pump 123 may be stopped according to the state transition of the second clock signal CLKa2 being stopped. For example, the counting block 122 may include a multiplexer that selects and outputs one of a signal having a frequency equal to the frequency of the first clock signal CLKa1 and a signal with state transition stopped depending on the comparison result signal.

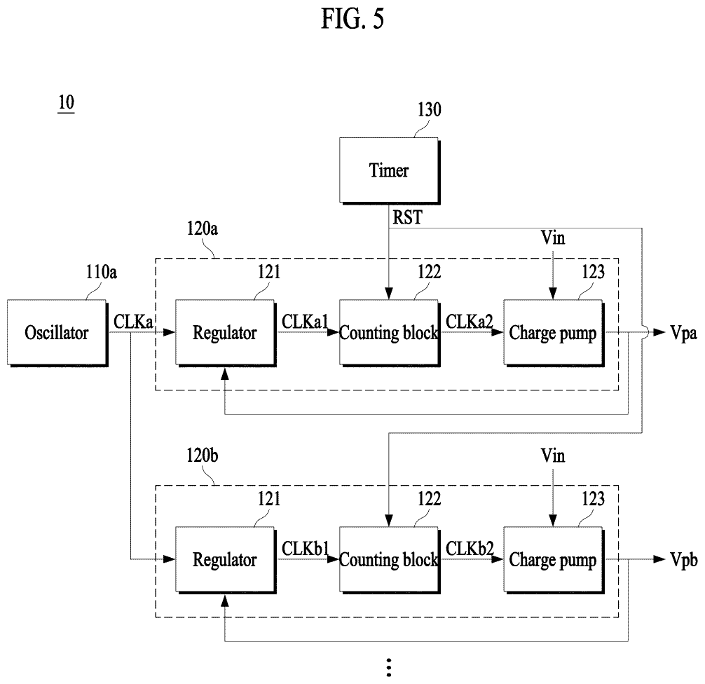

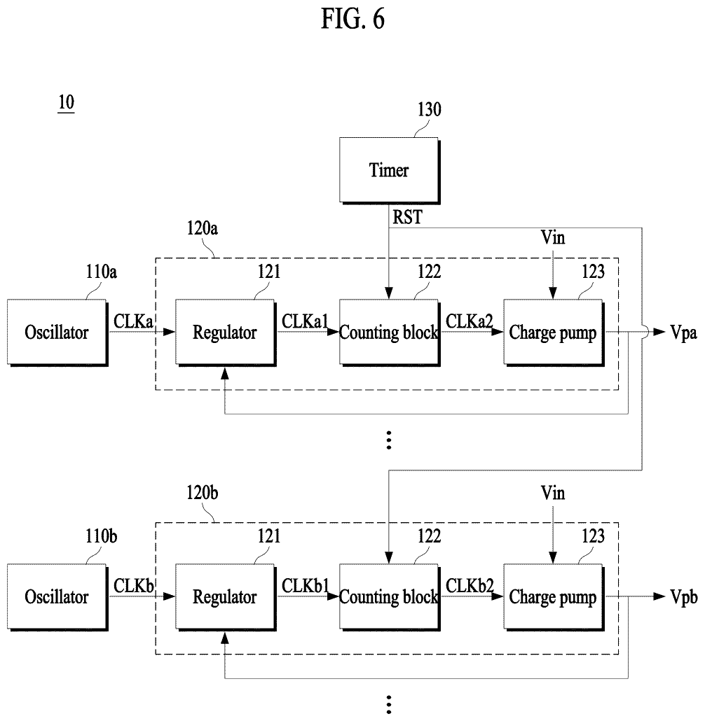

FIG. 5 is a diagram illustrating an example of a voltage generator including a plurality of charge pump blocks. FIG. 6 is a diagram illustrating an example of a voltage generator including a plurality of oscillators.

Referring to FIGS. 5 and 6, the voltage generator 10 may include the timer 130, at least one charge pump block 120a and 120b, and at least one oscillator 110a and 110b. In some example implementations, each charge pump block 120a and 120b may generate different levels of voltages. For example, the first charge pump block 120a may perform the amplifying operation on the input voltage Vin and generate a program voltage, and the second charge pump block 120b may perform the amplifying operation on the input voltage Vin and generate a power voltage for operating a peripheral circuit. However, this is merely one example implementation and may be variously modified and implemented.

Specifically, referring to FIG. 5, the voltage generator 10 may include the timer 130, the first charge pump block 120a, the second charge pump block 120b, and the first oscillator 110a. In this case, the first oscillator 110a may output the first reference clock signal CLKa, and the first charge pump block 120a and the second charge pump block 120b may perform the amplifying operation based on the first reference clock signal CLKa.

Specifically, referring to FIG. 6, the voltage generator 10 may include the timer 130, the first charge pump block 120a, the second charge pump block 120b, the first oscillator 110a, and the second oscillator 110b. In this case, the first oscillator 110a and the second oscillator 110b may output independent reference clock signals. For example, the first oscillator 110a may output the first reference clock signal CLKa, and the first charge pump block 120a may perform the amplifying operation based on the first reference clock signal CLKa. The second oscillator 110b may output a second reference clock signal CLKb, and the second charge pump block 120b may perform the amplifying operation based on the second reference clock signal CLKb.

Referring to FIGS. 5 and 6, each charge pump block 120a and 120b may generate the first clock signal CLKa1 and a first clock signal CLKb1 based on the reference clock signal CLKa and CLKb received from the connected oscillator 110a and 110b, respectively. For example, as shown in FIG. 5, the first charge pump block 120a and the second charge pump block 120b may be connected to the first oscillator 110a. In this case, the first charge pump block 120a may generate a first clock signal CLKa1 based on the first reference clock signal CLKa received from the first oscillator 110a. The second charge pump block 120b may generate a first clock signal CLKb1 based on the first reference clock signal CLKa received from the first oscillator 110a. In another example, as shown in FIG. 6, the first charge pump block 120a may be connected to the first oscillator 110a, and the second charge pump block 120b may be connected to the second oscillator 110b. In this case, the first charge pump block 120a may generate a first clock signal CLKa1 based on the first reference clock signal CLKa received from the first oscillator 110a. The second charge pump block 120b may generate a first clock signal CLKb1 based on the second reference clock signal CLKb received from the second oscillator 110b. Each charge pump block 120a and 120b may count the number of state transitions of the first clock signal CLKa1 and CLKb1 until the reset signal RST is received from the timer 130 and may perform the amplifying operation on the input voltage Vin based on the number of state transitions.

Each charge pump block 120a and 120b may include the counting block 122 and the charge pump 123. Each charge pump block 120a and 120b may further include the regulator 121. The counting block 122 of each charge pump block 120a and 120b may be connected in common to the timer 130.

In some example implementations, the number of the charge pump blocks 120a and 120b may be greater than or equal to the number of the oscillators 110a and 110b. In other words, the number of the charge pump blocks 120a and 120b may be equal to the number of the oscillators 110a and 110b or greater than the number of the oscillators 110a and 110b.

In some example implementations, the number of the charge pump blocks 120a and 120b may be equal to the number of the oscillators 110a and 110b. In this case, the oscillators 110a and 110b may be connected to the charge pump blocks 120a and 120b one-on-one.

In some example implementations, the number of the charge pump blocks 120a and 120b may be greater than the number of the oscillators 110a and 110b. In this case, each oscillator 110a and 110b may be connected to one or a plurality of charge pump blocks 120a and 120b.

In some example implementations, each charge pump block 120a and 120b may include the counting block 122 and the charge pump 123. Each counting block 122 may output the second clock signal CLKa2 or a second clock signal CLKb2 of which state transition to a frequency equal to a frequency of the first clock signal CLKa1 and CLKb1 is repeated or state transition is stopped depending on a result of comparing the number of state transitions of the first clock signal CLKa1 and CLKb1 and a set value. Each charge pump 123 may perform the amplifying operation on the input voltage Vin according to the state transition of the second clock signal CLKa2 and CLKb2.

In some example implementations, a set value of the counting block 122 included in the first charge pump block 120a among the plurality of charge pump blocks 120a and 120b may be different from a set value of the counting block 122 included in the second charge pump block 120b. In other words, a set value that is set for each counting block 122 may be different from each other. However, this is merely one example implementation, and a set value that is set for each counting block 122 may be identical to each other.

In some example implementations, each charge pump block 120a and 120b may further include the regulator 121. Each regulator 121 may output the first clock signal CLKa1 and CLKb1 of which a state is transitioned to a frequency equal to the reference frequency or to a frequency lower than the reference frequency depending on a result of comparing an output voltage Vpa and Vpb of each charge pump 123 and a reference voltage.

In some example implementations, a reference voltage of the regulator 121 included in the first charge pump block 120a among the plurality of charge pump blocks 120a and 120b may be different from a reference voltage of the regulator 121 included in the second charge pump block 120b. In other words, a reference voltage that is set for each regulator 121 may be different from each other. In this case, each output voltage Vpa and Vpb may have different levels.

The timer 130 may output the reset signal RST whenever the reference time elapses. In some example implementations, the timer 130 may output the reset signal RST in common to the counting block 122 of the first charge pump block 120a and the counting block 122 of the second charge pump block 120b. In other words, an identical reference time may be set for the counting block 122 of the first charge pump block 120a and the counting block 122 of the second charge pump block 120b.

Meanwhile, a connection structure of the counting block 122 may be modified and implemented.

In some example implementations, each of the plurality of charge pump blocks 120a and 120b may include the counting block 122 and the charge pump 123. For example, an output end of each counting block 122 may not be connected to an input end of each charge pump 123. Each counting block 122 and charge pump 123 may receive the first clock signal CLKa1 and CLKb1. The charge pump 123 may perform the amplifying operation based on the state transition of the first clock signal CLKa1. The counting block 122 may output a control signal after the number of state transitions of the first clock signal CLKa1 and CLKb1 reaches the set value. The control signal may be a signal for indirectly controlling the charge pump 123 by controlling other elements (for example, the regulator 121 and the oscillators 110a and 110b).

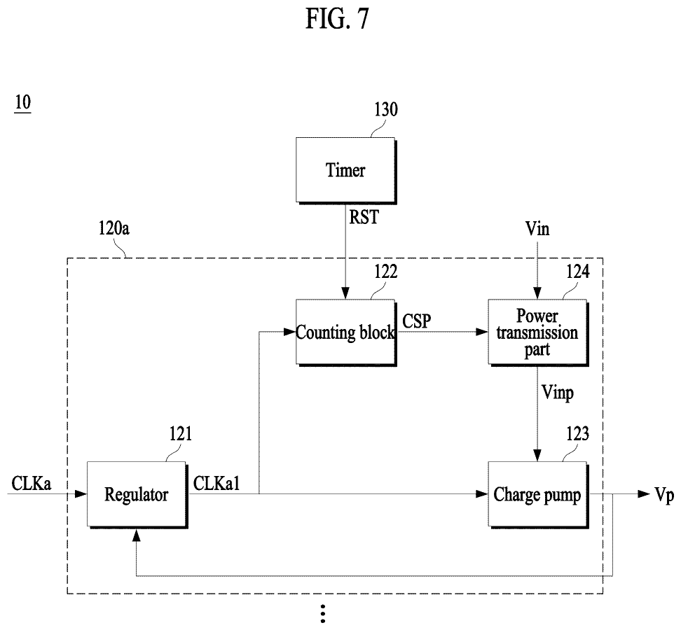

FIG. 7 is a diagram illustrating an example of a counting block that controls a power transmission part.

Referring to FIG. 7, the voltage generator 10 may further include a power transmission part 124 in addition to the timer 130, the counting block 122, and the charge pump 123. The power transmission part 124 may be included in the first charge pump block 120a including the counting block 122 and the charge pump 123.

The power transmission part 124 may supply the input voltage Vin or a driving voltage Vinp to the charge pump 123. A level of the driving voltage Vinp may be lower than a level of the input voltage Vin. For example, the power transmission part 124 may include a bypass circuit that transmits the input voltage Vin. The power transmission part 124 may further include various types of circuits such as a linear voltage regulator that reduces a level of the input voltage Vin and then outputs, a switching voltage regulator, a voltage divider, and a level shifter.

In some example implementations, the counting block 122 may receive the first clock signal CLKa1 and count the number of state transitions of the first clock signal CLKa1 for the reference time. The counting block 122 may output a control signal CSP to the power transmission part 124 based on the number of state transitions. Meanwhile, the charge pump 123 may receive the first clock signal CLKa1.

For example, the counting block 122 may output the control signal CSP in a first state to the power transmission part 124 until the number of state transitions reaches a set value. The control signal CSP in the first state may be a signal for controlling that the power transmission part 124 supplies the input voltage Vin. In this case, the charge pump 123 may perform the amplifying operation on the input voltage Vin according to the state transition of the first clock signal CLKa1.

For example, the counting block 122 may output the control signal CSP in a second state to the power transmission part 124 after the number of state transitions reaches a set value. The control signal CSP in the second state may be a signal for controlling that the power transmission part 124 supplies the driving voltage Vinp that is lower than the input voltage Vin. In this case, the charge pump 123 may perform the amplifying operation on the driving voltage Vinp according to the state transition of the first clock signal CLKa1. Since the amplifying operation is performed with the driving voltage Vinp, which is lower than the input voltage Vin, the current consumption may be further reduced.

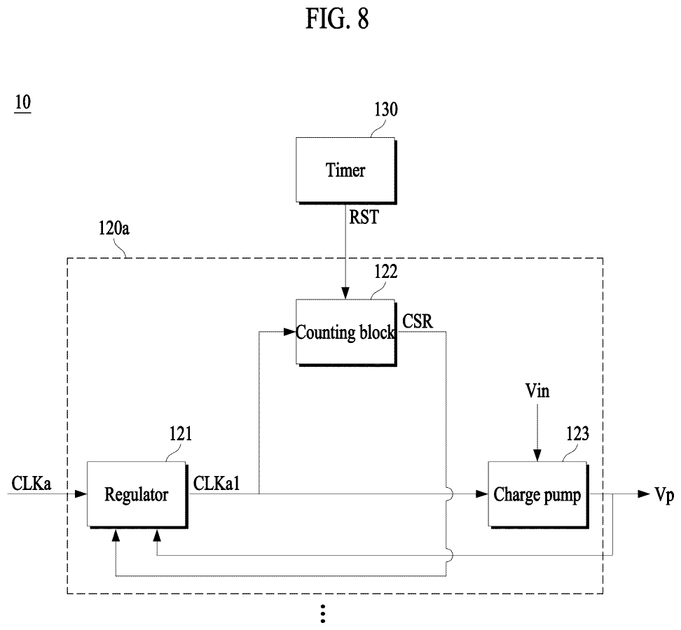

FIG. 8 is a diagram illustrating an example of a counting block that controls a regulator.

Referring to FIG. 8, the voltage generator 10 may further include the regulator 121 in addition to the timer 130, the counting block 122, and the charge pump 123. The regulator 121 may be included in the charge pump block 120a including the counting block 122 and the charge pump 123.

In some example implementations, the regulator 121 may receive the reference clock signal CLKa having the reference frequency and output the first clock signal CLKa1 corresponding to the reference clock signal CLKa according to the output voltage Vp of the charge pump 123. For example, the regulator 121 may output the first clock signal CLKa1 having a frequency equal to the reference frequency when the output voltage Vp of the charge pump 123 is less than a reference voltage and output the first clock signal CLKa1 having a frequency lower than the reference frequency when the output voltage Vp of the charge pump 123 is greater than or equal to the reference voltage.

In some example implementations, the counting block 122 may receive the first clock signal CLKa1 and count the number of state transitions of the first clock signal CLKa1 for the reference time. The counting block 122 may output a control signal CSR to the regulator 121 based on the number of state transitions. Meanwhile, the charge pump 123 may receive the first clock signal CLKa1.

In some example implementations, the counting block 122 may output the control signal CSR in a first state to the regulator 121 until a first number of state transitions reaches a set value for the reference time. For example, the control signal CSR in the first state may be a signal that controls the output of the first clock signal CLKa1 with state transition repeated according to frequencies.

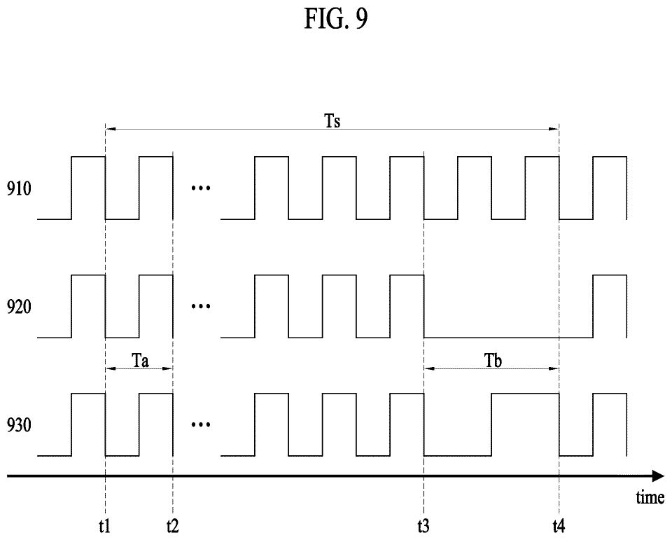

In some example implementations, the counting block 122 may output the control signal CSR in a second state to the regulator 121 after the first number of state transitions reaches a set value. In some example implementations, the control signal CSR in the second state may be a signal that controls the output of the first clock signal CLKa1 with state transition stopped. In some example implementations, the control signal CSR in the second state may be a signal that controls the output of the first clock signal CLKa1 having a frequency lower than the reference frequency of the reference clock signal CLKa. This is described in detail with reference to FIG. 9.

FIG. 9 is a diagram illustrating waveforms of an example of a clock signal.

Referring to FIG. 9, a first waveform 910 represents a waveform of the reference clock signal CLKa inputted to the regulator 121, a second waveform 920 represents a waveform of the first clock signal CLKa1 adjusted in a first control manner of the counting block 122, and a third waveform 930 represents a waveform of the first clock signal CLKa1 adjusted in a second control manner of the counting block 122. Meanwhile, FIG. 9 illustrates that time is identical in the waveforms of the reference clock signal CLKa and the first clock signal CLKa1, but a delay time may be present between the signals.

In some example implementations, the regulator 121 may receive the reference clock signal CLKa and output the first clock signal CLKa1 corresponding to the reference clock signal CLKa. The reference clock signal CLKa may be a signal in which state transition occurs by the first period Ta corresponding to the reference frequency. The first clock signal CLKa1 may be a signal in which state transition occurs by the period Ta corresponding to a frequency equal to the reference frequency. The first clock signal CLKa1 may be adjusted based on a control by the counting block 122.

In some example implementations, the counting block 122 may count the number of state transitions of the first clock signal CLKa1, such as the first waveform 910, during the reference time Ts. Here, at a third time point t3 within the reference time Ts, the number of state transitions may reach a set value.

In some example implementations, after the third time point t3 when the number of state transitions reaches the set value, the counting block 122 may output the control signal CSR to the regulator 121 for controlling that the first clock signal CLKa1 with state transition stopped is outputted. In this case, the regulator 121 may output the first clock signal CLKa1 having the second waveform 920 when the control signal is received.

In some example implementations, after the third time point t3 when the number of state transitions reaches the set value, the counting block 122 may output the control signal CSR to the regulator 121 for controlling that the first clock signal CLKa1 having a frequency lower than the reference frequency of the reference clock signal CLKa is outputted. In this case, the regulator 121 may output the first clock signal CLKa1 having the third waveform 930 when the control signal is received. The first clock signal CLKa1 may be a signal in which state transition occurs by a second period Tb corresponding to a frequency lower than the reference frequency of the reference clock signal CLKa. The second period Tb may be longer than the first period Ta.

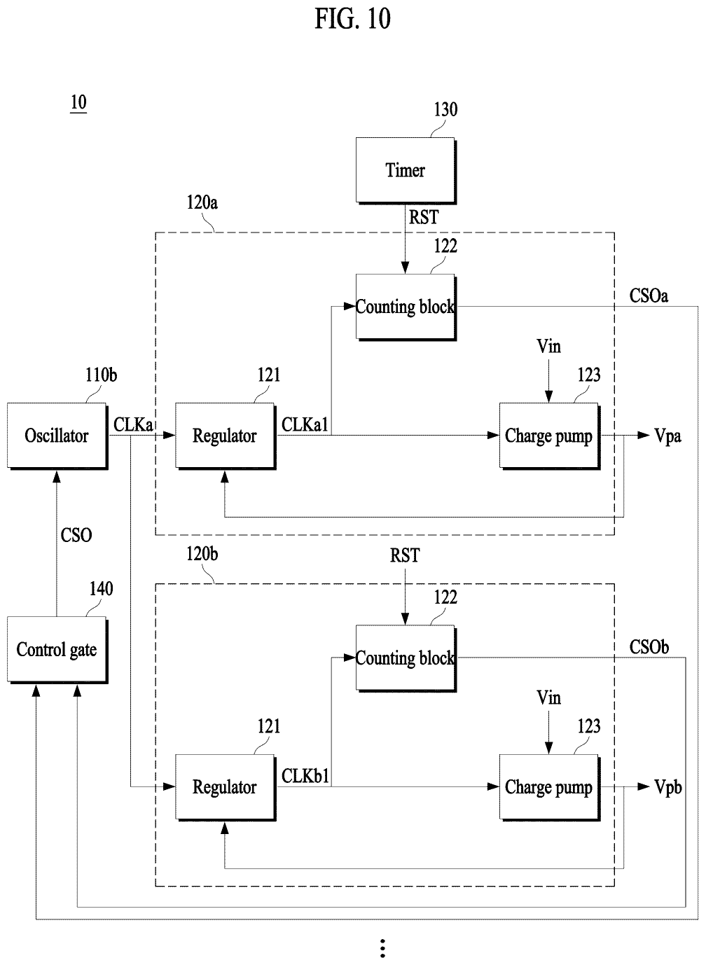

FIG. 10 is a diagram illustrating an example of a counting block that controls an oscillator.

Referring to FIG. 10, the voltage generator 10 may further include the oscillator 110a in addition to the timer 130, the counting block 122, and the charge pump 123. In some example implementations, the voltage generator 10 may further include a control gate 140.

In some example implementations, the counting block 122 may receive the first clock signal CLKa1 and CLKb1 corresponding to the reference clock signal CLKa of the oscillator 110a and count the number of state transitions of the first clock signal CLKa1 and CLKb1 for the reference time. Meanwhile, the charge pump 123 may receive the first clock signal CLKa1 and CLKb1.

In some example implementations, the counting block 122 may output a control signal to the oscillator 110a based on the number of state transitions for the reference time. The counting block 122 may directly output the control signal to the oscillator 110a based on the number of state transitions or output through the control gate 140 to the oscillator 110a.

In some example implementations, after the number of state transitions for the reference time reaches a set value, the counting block 122 may output a control signal to the oscillator 110a for controlling that the reference signal CLKa with state transition stopped is outputted. In some example implementations, after the number of state transitions reaches the set value, the counting block 122 may output a control signal to the oscillator 110a for controlling that the reference clock signal CLKa having a frequency lower than the reference frequency is outputted. The descriptions with reference to FIG. 9 may be identically applied to this.

In some example implementations, the voltage generator 10 may include the plurality of charge pump blocks 120a and 120b. The plurality of charge pump blocks 120a and 120b may be connected to the single oscillator 110a. Each of the plurality of charge pump blocks 120a and 120b may include the counting block 122 and the charge pump 123. Each of the plurality of charge pump blocks 120a and 120b may further include the regulator 121.

In some example implementations, when a first control signal is received from all the charge pump blocks 120a and 120b connected to the single oscillator 110a, the control gate 140 may output a second control signal CSO to the single oscillator 110a. Here, the second control signal CSO may be a signal for controlling that a frequency of the reference clock signal CLKa outputted from the single oscillator 110a is reduced or the state transition of the reference clock signal CLKa is stopped. For example, the control gate 140 may include an AND gate that outputs the second control signal CSO on condition that the first control signal is all received from each of the charge pump blocks 120a and 120b.

In some example implementations, when the first control signal is received from at least one of all the charge pump blocks 120a and 120b connected to the single oscillator 110a, the control gate 140 may output the second control signal to the single oscillator 110a. Here, the second control signal CSO may be a signal for controlling that a frequency of the reference clock signal CLKa outputted from the single oscillator 110a is reduced or the state transition of the reference clock signal CLKa is stopped. For example, the control gate 140 may include an OR gate that outputs the second control signal CSO on condition that the first control signal is received from one of all the charge pump blocks 120a and 120b.

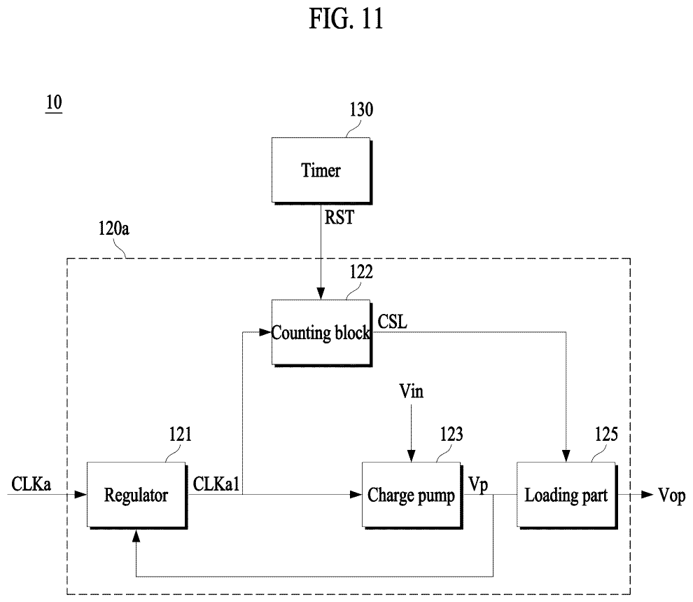

FIG. 11 is a diagram illustrating an example of a counting block that controls a loading part.

Referring to FIG. 11, the voltage generator 10 may further include a loading part 125 in addition to the timer 130, the counting block 122, and the charge pump 123. The loading part 125 may be included in the charge pump block 120a including the counting block 122 and the charge pump 123.

In some example implementations, the counting block 122 may receive the first clock signal CLKa1 corresponding to the reference clock signal CLKa of the oscillator 110a and count the number of state transitions of the first clock signal CLKa1 for the reference time. Meanwhile, the charge pump 123 may receive the first clock signal CLKa1 and perform the amplifying operation on the input voltage Vin according to the state transition of the first clock signal CLKa1 and output the output voltage Vp.

In some example implementations, the counting block 122 may output a control signal CSL to the loading part 125 based on the number of state transitions. For example, the counting block 122 may output the control signal CSL in a first state for setting a general mode to the loading part 125 until the number of state transitions reaches a set value. The counting block 122 may output the control signal CSL in a second state for setting a low-power mode to the loading part 125 after the number of state transitions reaches a set value. The low-power mode may be a mode of reducing a slope of the output voltage Vp.

In some example implementations, the loading part 125 may operate using the output voltage Vp of the charge pump 123. For example, the loading part 125 may generate an operating voltage Vop using the output voltage Vp. For example, the operating voltage Vop may be one of various voltages such as a program voltage, a read voltage, an erase voltage, and the like.

In some example implementations, the loading part 125 may operate using the output voltage Vp of the charge pump 123 according to one mode set among a first mode and a second mode. For example, the first mode may be the general mode and the second mode may be the low-power mode. When the low-power mode is set, the loading part 125 may operate using the output voltage Vp with a slope reduced. The slope may refer to a changing speed of a voltage, and the current consumption of the charge pump block 120a may decrease when the slope is reduced.

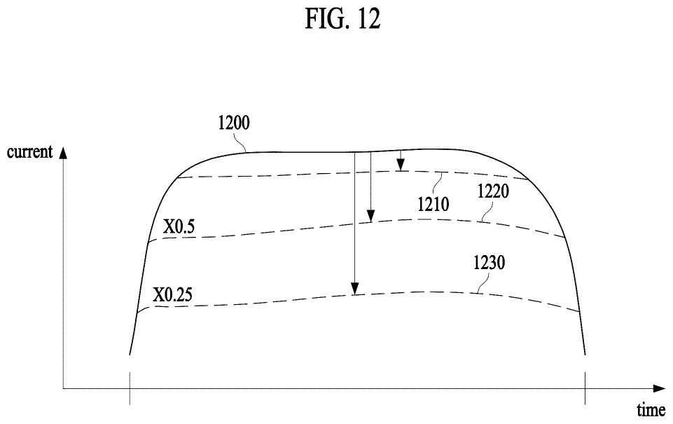

FIG. 12 is a diagram illustrating an example of current consumption.

Referring to FIG. 12, a reference graph 1200 indicates general current consumption and a first graph 1210 indicates current consumption when a reference time is set. A second graph 1220 and a third graph 1230 indicate current consumption when a frequency of a clock signal is reduced in integer multiples with no setting of the reference time.

For the second graph 1220 and the third graph 1230, a frequency of a clock signal may be reduced in integer multiples using a frequency divider or the like. In this case, current consumption is also reduced in integer multiples, which may make it difficult to adjust by detailed units.

For the first graph 1210, current consumption may be adjusted by detailed units through the reference time and the set value. In some example implementations of the present disclosure, current consumption may be precisely adjusted, which may improve stability and efficiency in the voltage generator 10.

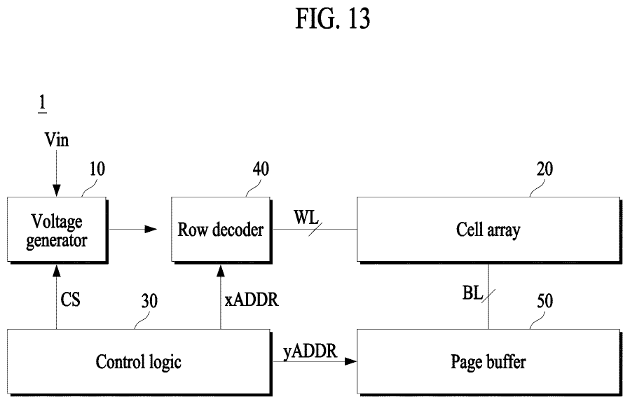

FIG. 13 is a diagram illustrating an example of a memory device.

Referring to FIG. 13, a memory device 1 may include the voltage generator 10 and a cell array 20.

The voltage generator 10 may generate an operating voltage applied to a memory cell. The operating voltage may be various voltages such as a program voltage, a read voltage, and an erase voltage.

In some example implementations, the voltage generator 10 may include the charge pump 123, the counting block 122, and the timer 130. The charge pump 123 may perform an amplifying operation on an input voltage based on a clock signal and generate an operating voltage. The counting block 122 may count the number of state transitions of the clock signal for a reference time and control the charge pump 123 based on the number of state transitions. The timer 130 may initialize the number of state transitions when the reference time Ts elapses.

The cell array 20 may include a plurality of memory cells. The memory cell may be a semiconductor device that stores data. For example, the memory cell may be implemented as various types of semiconductor devices such as NAND flash memory, NOR flash memory, ferroelectric random access memory (FRAM), phase-change random access memory (PCRAM), magnetic random access memory (MRAM), dynamic random access memory (DRAM), and static random access memory (SRAM).

The plurality of memory cells may be divided based on rows and columns. A word line WL represents one row and a bit line BL represents one column. The plurality of memory cells connected to different bit lines may be connected to one word line WL. Depending on an operating voltage applied to the word line WL, the plurality of memory cells connected to the word line WL may perform a corresponding operation. When the operating voltage is a program voltage, the plurality of memory cells connected to the word line WL may store data transmitted through each bit line BL. When the operating voltage is a read voltage, the plurality of memory cells connected to the word line WL may transmit the stored data through each bit line BL.

The memory device 1 may further include a peripheral circuit. The peripheral circuit may include a control logic 30, a row decoder 40, and a page buffer 50.

The control logic 30 may control an overall operation of the memory device 1.

In some example implementations, the control logic 30 may transmit a control signal CS to the voltage generator. In some example implementations, the control signal CS may be a signal that controls a timing of an operation. For example, the control signal CS may include a signal that changes the reference time of the timer 130 inside the voltage generator 10. For another example, the control signal CS may include a system clock signal for identifying time by the timer 130 inside the voltage generator 10.

The control logic 30 may transmit row address xADDR to the row decoder 40 and transmit column address yADDR to the page buffer 50 in order to perform an operation. The word line WL may be selected by the row address xADDR and the bit line BL may be selected by the column address yADDR.

The row decoder 40 may select one word line among a plurality of word lines WL in response to the row address xADDR. The row decoder 40 may apply an operating voltage supplied from the voltage generator 10 to the selected word line. For example, the row decoder 40 may apply a program voltage (or a read voltage) to the selected word line and apply a pass voltage to an unselected word line.

The page buffer 50 may transmit and receive data to and from at least one of the cell array 20 and an outside of the memory device 1. The page buffer 50 may select at least one bit line among a plurality of bit lines BL in response to the column address yADDR. The page buffer 50 may transmit data to the selected bit line or receive data from the selected bit line.

The memory device according to the above-described example implementations may include a processor, a memory for storing and executing program data, a permanent storage such as a disk drive, a communication port that communicates with an external device, and a user interface device such as a touch panel, a key, and a button. Methods implemented as software modules or algorithms may be stored in a computer-readable recording medium as computer-readable codes or program instructions executable on the processor. Here, the computer-readable recording medium includes a magnetic storage medium (for example, read-only memory (ROM), random-access memory (RAM), floppy disks, and hard disks) and an optically readable medium (for example, CD-ROM and digital versatile discs (DVDs)). The computer-readable recording medium may be distributed among network-connected computer systems, so that the computer-readable codes may be stored and executed in a distributed manner. The medium may be readable by a computer, stored in a memory, and executed on a processor.

The example implementations may be represented by functional block elements and various processing steps. The functional blocks may be implemented in any number of hardware and/or software configurations that perform specific functions. For example, an example implementation may adopt integrated circuit configurations, such as memory, processing, logic, and/or look-up table, that may execute various functions by the control of one or more microprocessors or other control devices. Similarly to that elements may be implemented as software programming or software elements, the example implementations may be implemented in a programming or scripting language such as C, C++, Java, assembler, etc., including various algorithms implemented as a combination of data structures, processes, routines, or other programming constructs. Functional aspects may be implemented in an algorithm running on one or more processors. Further, the example implementations may adopt the existing art for electronic environment setting, signal processing, and/or data processing. Terms such as “mechanism,” “element,” “means,” and “configuration” may be used broadly and are not limited to mechanical and physical configurations. The terms may include the meaning of a series of routines of software in association with a processor or the like.

The above-described example implementations are merely examples, and other example implementations may be implemented within the scope of the claims to be described later.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A voltage generator comprising:
a charge pump configured to perform an amplifying operation on an input voltage;
a counting block configured to
count a number of state transitions of a first clock signal for a reference time, and
control the charge pump based on the number of state transitions; and
a timer configured to initialize the number of state transitions based on the reference time being elapsed.

2. The voltage generator of claim 1, wherein the counting block is configured to, based on the number of state transitions being less than a set value, output a second clock signal to the charge pump, the second clock signal having a same frequency as the first clock signal, and
wherein the charge pump is configured to perform the amplifying operation according to a state transition of the second clock signal.

3. The voltage generator of claim 2, wherein the counting block is configured to, based on the number of state transitions reaching the set value, output, to the charge pump, the second clock signal with the state transition being stopped, and
wherein the charge pump is configured to stop the amplifying operation according to the state transition of the second clock signal being stopped.

4. The voltage generator of claim 1, comprising:
an oscillator configured to output a reference clock signal having a reference frequency; and
a regulator configured to output the first clock signal according to an output voltage of the charge pump, the first clock signal corresponding to the reference clock signal, the output voltage being a voltage to which the input voltage is amplified,
wherein the charge pump is configured to perform the amplifying operation according to a state transition of the first clock signal.

5. The voltage generator of claim 4, wherein the counting block is configured to, based on the number of state transitions reaching a set value, output a first control signal to the regulator, and
wherein the regulator is configured to output, based on the first control signal, the first clock signal with the state transition being stopped.

6. The voltage generator of claim 4, wherein the counting block is configured to, based on the number of state transitions reaching a set value, output a second control signal to the regulator, and
wherein the regulator is configured to output, based on the second control signal, the first clock signal having a frequency lower than the reference frequency.

7. The voltage generator of claim 4, wherein the counting block is configured to, based on the number of state transitions reaching a set value, output a third control signal to the oscillator, and
wherein the oscillator is configured to output, based on the third control signal, the reference clock signal with the state transition being stopped.

8. The voltage generator of claim 4, wherein the counting block is configured to, based on the number of state transitions reaching a set value, output a fourth control signal to the oscillator, and
wherein the oscillator is configured to output, based on the fourth control signal, the reference clock signal having a frequency lower than the reference frequency.

9. The voltage generator of claim 4, wherein the regulator is configured to, based on the output voltage of the charge pump being less than a reference voltage, output the first clock signal having a frequency equal to the reference frequency, and
wherein the regulator is configured to, based on the output voltage of the charge pump being greater than or equal to the reference voltage, output the first clock signal having a frequency lower than the reference frequency.

10. The voltage generator of claim 1, comprising a power transmission part configured to supply a driving voltage lower than or equal to the input voltage to the charge pump,
wherein the counting block is configured to, based on the number of state transitions reaching a set value, output a fifth control signal to the power transmission part, and
wherein the power transmission part is configured to supply, based on the fifth control signal, the driving voltage lower than the input voltage to the charge pump.

11. The voltage generator of claim 1, comprising a loading part configured to operate based on an output voltage of the charge pump,
wherein the counting block is configured to, based on the number of state transitions reaching a set value, output a sixth control signal to the loading part, and
wherein the loading part is configured to set, based on the sixth control signal, a low-power mode of reducing a slope of the output voltage.

12. A voltage generator comprising:
a timer configured to output a reset signal based on a reference time being elapsed;
a plurality of oscillators configured to output a plurality of reference clock signals having a plurality of reference frequencies, respectively; and
a plurality of charge pump blocks configured to
generate a first clock signal based on a reference clock signal received from a connected oscillator among the plurality of oscillators,
count a number of state transitions of the first clock signal until the reset signal is received, and
perform an amplifying operation on an input voltage based on the number of state transitions,
wherein a number of the plurality of charge pump blocks is greater than or equal to a number of the plurality of oscillators.

13. The voltage generator of claim 12, wherein each charge pump block of the plurality of charge pump blocks includes:
a counting block configured to output a second clock signal, the second clock signal being configured to have a state transition to a frequency equal to a frequency of the first clock signal, the state transition being repeated or stopped based on a result of comparing the number of state transitions of the first clock signal and a set value; and
a charge pump configured to perform the amplifying operation on the input voltage according to the state transition of the second clock signal.

14. The voltage generator of claim 13, wherein a set value of a counting block included in a first charge pump block among the plurality of charge pump blocks is different from a set value of a counting block included in a second charge pump block among the plurality of charge pump blocks.

15. The voltage generator of claim 12, wherein each charge pump block of the plurality of charge pump blocks includes a regulator, the regulator being configured to generate the first clock signal, the first clock signal being configured to have a state transition to a frequency equal to or lower than the reference frequency based on a result of comparing an output voltage of the charge pump and a reference voltage.

16. The voltage generator of claim 15, wherein a reference voltage of a regulator included in a first charge pump block among the plurality of charge pump blocks is different from a reference voltage of a regulator included in a second charge pump block among the plurality of charge pump blocks.

17. The voltage generator of claim 12, wherein each charge pump block of the plurality of charge pump blocks includes:
a charge pump configured to perform the amplifying operation according to a state transition of the first clock signal; and
a counting block configured to output a first control signal based on the number of state transitions of the first clock signal reaching a set value.

18. The voltage generator of claim 17, comprising a control gate configured to, based on receiving the first control signal from all charge pump blocks connected with a first oscillator included in the plurality of oscillators, output a second control signal to the first oscillator, the first oscillator being configured to, based on the second control signal, decrease a frequency of a first reference clock signal outputted from the first oscillator or to stop state transition.

19. The voltage generator of claim 17, comprising a control gate configured to, based on receiving the first control signal from at least one charge pump block connected with a first oscillator included in the plurality of oscillators, output a second control signal to the first oscillator, the first oscillator being configured to, based on the second control signal, decrease a frequency of a first reference clock signal outputted from the first oscillator or to stop state transition.

20. A memory device comprising:
a cell array including a plurality of memory cells; and
a voltage generator configured to generate an operating voltage applied to at least one memory cell among the plurality of memory cells,
wherein the voltage generator includes:
a charge pump configured to
perform an amplifying operation on an input voltage based on a clock signal, and
generate the operating voltage;
a counting block configured to
count a number of state transitions of the clock signal for a reference time, and
control the charge pump based on the number of state transitions; and
a timer configured to initialize the number of state transitions based on the reference time being elapsed.
